(19) United States
(12) Patent Application Publication
(10) Pub. No.: US 2023/0352497 A1
(43) Pub. Date: Nov. 2, 2023

(54) Methods of Forming Bent Display Panels

(71) Applicant: Apple Inc., Cupertino, CA (US)

(72) Inventors: Meng-Tse Chen, Hsinchu (TW); Anshi Liang, Saratoga, CA (US); Arnoldus A Barlian, San Francisco, CA (US); Bayu A Thedjoisworo, Palo Alto, CA (US); Boris A Russ, San Jose, CA (US); Chun-Hsien Lee, Hsinchu (TW); Chun-Lan Wu, Sunnyvale, CA (US); Han-Chieh Chang, Sunnyvale, CA (US); Jiming Yu, Shanghai (CN); Marc J DeVincentis, Palo Alto, CA (US); Nathan K Gupta, Hillsborough, CA (US); Paolo Sacchetto, Cupertino, CA (US); Paul S Drzaic, Morgan Hill, CA (US); Zhen Zhang, Sunnyvale, CA (US); Ziyang Zhang, Foster City, CA (US)

(21) Appl. No.: 18/176,931

(22) Filed: Mar. 1, 2023

Related U.S. Application Data
(60) Provisional application No. 63/337,476, filed on May 2, 2022.

(51) Int. Cl. H01L 27/12; H01L 25/16; H05K 3/10; H05K 1/02; H05K 3/32

(52) U.S. Cl. CPC H01L 27/1296; H01L 25/167; H01L 27/1248; H05K 3/107; H05K 1/028; H05K 3/321

(57) ABSTRACT

A display may have one or more bent portions. To increase the magnitude of curvature in a display and/or to allow for compound curvature in the display, a display panel may be partially formed in a planar state. The partial display panel is then bent to have desired curvature. After the partial display panel is bent, additional display components that are susceptible to damage during the bending process may be added to complete the display panel. A flexible printed circuit may be formed directly on the display panel using precise deposition of conductive material. By forming the flexible printed circuit layer-by-layer directly on the display panel, no substantive pressure needs to be applied to the display panel. Electrical connections may therefore be made to the display panel in regions of the display with high levels of curvature and/or with compound curvature without causing front-of-screen artifacts for the display panel.

This application claims the benefit of U.S. Provisional Patent Application No. 63/337,476, filed May 2, 2022, which is hereby incorporated by reference herein in its entirety.

### BACKGROUND

This relates generally to electronic devices, and, more particularly, to electronic devices with displays.

Electronic devices often include displays. For example, an electronic device may have a light-emitting diode (LED) display based on light-emitting diode pixels or a liquid crystal display (LCD) based on liquid crystal display pixels. It may be desirable for a display to have one or more bent portions. However, if care is not taken, it may be difficult to manufacture a robust display with bent portions.

### SUMMARY

An electronic device may have a display such as a light-emitting diode display. The display may have one or more bent portions. The bent portions may optionally include compound curvature.

To increase the magnitude of curvature in a display and/or to allow for compound curvature in the display, a display panel may be partially formed in a planar state (including some but not all of the final display components). The partial display panel is then bent/molded to have desired curvature. After the partial display panel is bent, additional display components that are susceptible to damage during the bending process may be added to complete the display panel. As an example, conductive traces formed from indium tin oxide may be added to the display panel after the partial display panel is bent.

A flexible printed circuit may be formed directly on the display panel using precise deposition of conductive material. By forming the flexible printed circuit layer-by-layer directly on the display panel, no substantive pressure needs to be applied to the display panel (mitigating artifacts associated with lamination pressure). Electrical connections may therefore be made to the display panel in regions of the display with high levels of curvature and/or with compound curvature without causing front-of-screen artifacts for the display panel. Electrical components may optionally be embedded in the flexible printed circuit. The electrical components may be attached to conductive and/or insulating layers in the flexible printed circuit with die attach films.

### BRIEF DESCRIPTION OF THE DRAWINGS

FIG. 1 is a schematic diagram of an illustrative electronic device having a display in accordance with various embodiments.

FIG. 2 is a schematic diagram of an illustrative display in accordance with various embodiments.

FIG. 3 is a schematic diagram of an illustrative display with pixel control circuits in accordance with various embodiments.

FIG. 4 is a schematic diagram of an illustrative passive matrix of light-emitting diodes that is controlled by a pixel control circuit in accordance with various embodiments.

FIG. 5 is a cross-sectional side view of an illustrative planar portion of a display cover layer and pixel array in accordance with various embodiments.

FIG. 6 is a cross-sectional side view of an illustrative curved portion of a display cover layer and pixel array in accordance with various embodiments.

FIG. 7 is a cross-sectional side view of an illustrative sidewall portion of an electronic device in accordance with various embodiments.

FIG. 8 is a top view of an illustrative corner portion of an electronic device in accordance with various embodiments.

FIG. 9 is a cross-sectional side view of an illustrative method for forming a bent display panel where a completed display panel is molded to have desired curvature in accordance with various embodiments.

FIG. 10 is a cross-sectional side view of an illustrative method for forming a bent display panel where a partial display panel is molded to have desired curvature then additional conductive components are formed on the curved partial display panel in accordance with various embodiments.

FIG. 11 is a cross-sectional side view of an illustrative display panel having a planar central portion and curved edge portions in accordance with various embodiments.

FIGS. 12A and 12B are cross-sectional side views of an illustrative method for forming a flexible printed circuit layer-by-layer directly on a lower surface of a display panel in accordance with various embodiments.

FIG. 13 is a flowchart of illustrative method steps for forming a bent display panel by molding a partial display panel to have desired curvature before adding some conductive components to the curved partial display panel in accordance with various embodiments.

FIG. 14 is a flowchart of illustrative method steps for forming a flexible printed circuit layer-by-layer directly on a lower surface of a display panel in accordance with various embodiments.

### DETAILED DESCRIPTION

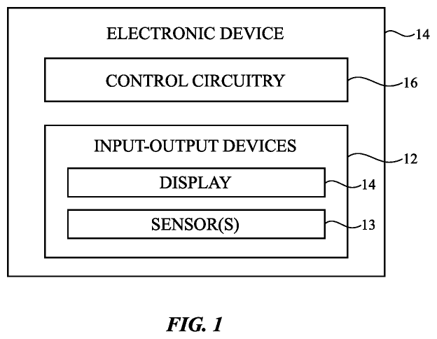

An illustrative electronic device of the type that may be provided with a display is shown in FIG. 1. Electronic device 10 may be a computing device such as a laptop computer, a computer monitor containing an embedded computer, a tablet computer, a cellular telephone, a media player, or other handheld or portable electronic device, a smaller device such as a wrist-watch device, a pendant device, a headphone or earpiece device, a device embedded in eyeglasses or other equipment worn on a user's head, or other wearable or miniature device, a display, a computer display that contains an embedded computer, a computer display that does not contain an embedded computer, a gaming device, a navigation device, an embedded system such as a system in which electronic equipment with a display is mounted in a kiosk or automobile, or other electronic equipment. Electronic device 10 may have the shape of a pair of eyeglasses (e.g., supporting frames), may form a housing having a helmet shape, or may have other configurations to help in mounting and securing the components of one or more displays on the head or near the eye of a user.

As shown in FIG. 1, electronic device 10 may include control circuitry 16 for supporting the operation of device 10. Control circuitry 16 may include storage such as hard disk drive storage, nonvolatile memory (e.g., flash memory or other electrically-programmable-read-only memory configured to form a solid-state drive), volatile memory (e.g., static or dynamic random-access memory), etc. Processing circuitry in control circuitry 16 may be used to control the operation of device 10. The processing circuitry may be based on one or more microprocessors, microcontrollers, digital signal processors, baseband processors, power management units, audio chips, application-specific integrated circuits, etc.

Input-output circuitry in device 10 such as input-output devices 12 may be used to allow data to be supplied to device 10 and to allow data to be provided from device 10 to external devices. Input-output devices 12 may include buttons, joysticks, scrolling wheels, touch pads, key pads, keyboards, microphones, speakers, tone generators, vibrators, cameras, sensors, light-emitting diodes and other status indicators, data ports, etc. A user can control the operation of device 10 by supplying commands through input resources of input-output devices 12 and may receive status information and other output from device 10 using the output resources of input-output devices 12.

Input-output devices 12 may include one or more displays such as display 14. Display 14 may be a touch screen display that includes a touch sensor for gathering touch input from a user or display 14 may be insensitive to touch. A touch sensor for display 14 may be based on an array of capacitive touch sensor electrodes, acoustic touch sensor structures, resistive touch components, force-based touch sensor structures, a light-based touch sensor, or other suitable touch sensor arrangements. A touch sensor for display 14 may be formed from electrodes formed on a common display substrate with the display pixels of display 14 or may be formed from a separate touch sensor panel that overlaps the pixels of display 14. If desired, display 14 may be insensitive to touch (i.e., the touch sensor may be omitted). Display 14 in electronic device 10 may be a head-up display that can be viewed without requiring users to look away from a typical viewpoint or may be a head-mounted display that is incorporated into a device that is worn on a user's head. If desired, display 14 may also be a holographic display used to display holograms.

Control circuitry 16 may be used to run software on device 10 such as operating system code and applications. During operation of device 10, the software running on control circuitry 16 may display images on display 14.

Input-output devices 12 may also include one or more sensors 13 such as force sensors (e.g., strain gauges, capacitive force sensors, resistive force sensors, etc.), audio sensors such as microphones, touch and/or proximity sensors such as capacitive sensors (e.g., a two-dimensional capacitive touch sensor associated with a display and/or a touch sensor that forms a button, trackpad, or other input device not associated with a display), and other sensors. In accordance with some embodiments, sensors 13 may include optical sensors such as optical sensors that emit and detect light (e.g., optical proximity sensors such as transreflective optical proximity structures), ultrasonic sensors, and/or other touch and/or proximity sensors, monochromatic and color ambient light sensors, image sensors (cameras), fingerprint sensors, temperature sensors, proximity sensors and other sensors for measuring three-dimensional non-contact gestures (“air gestures”), pressure sensors, sensors for detecting position, orientation, and/or motion (e.g., accelerometers, magnetic sensors such as compass sensors, gyroscopes, and/or inertial measurement units that contain some or all of these sensors), health sensors, radio-frequency sensors, depth sensors (e.g., structured light sensors and/or depth sensors based on stereo imaging devices), optical sensors such as self-mixing sensors and light detection and ranging (lidar) sensors that gather time-of-flight measurements, humidity sensors, moisture sensors, gaze tracking sensors, and/or other sensors. In some arrangements, device 10 may use sensors 13 and/or other input-output devices to gather user input (e.g., buttons may be used to gather button press input, touch sensors overlapping displays can be used for gathering user touch screen input, touch pads may be used in gathering touch input, microphones may be used for gathering audio input, accelerometers may be used in monitoring when a finger contacts an input surface and may therefore be used to gather finger press input, etc.).

Display 14 may be an organic light-emitting diode display, a display formed from an array of discrete light-emitting diodes (microLEDs) each formed from a crystalline semiconductor die, a liquid crystal display, or any other suitable type of display. Device configurations in which display 14 includes microLEDs are sometimes described herein as an example. This is, however, merely illustrative. Any suitable type of display may be used, if desired. In general, display 14 may have a rectangular shape (i.e., display 14 may have a rectangular footprint and a rectangular peripheral edge that runs around the rectangular footprint) or may have other suitable shapes. Display 14 may be planar or may have a curved profile.

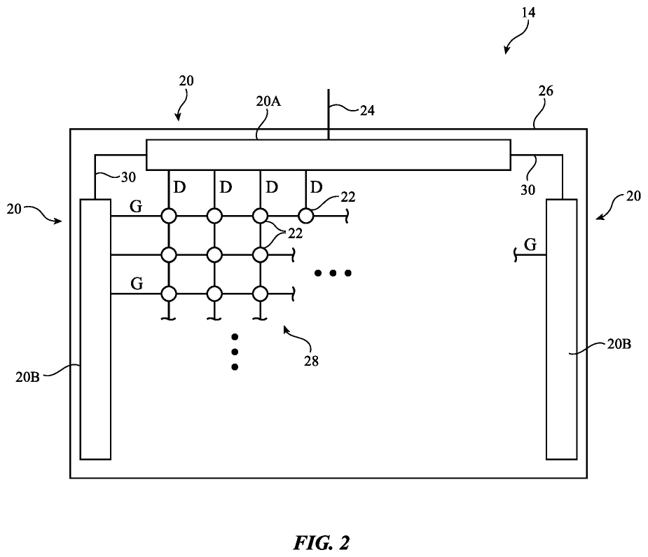

FIG. 2 is a diagram of an illustrative display. The display of FIG. 2 is an active matrix display. As shown in FIG. 2, display 14 may include layers such as substrate layer 26. Substrate layers such as layer 26 may be formed from rectangular planar layers of material or layers of material with other shapes (e.g., circular shapes or other shapes with one or more curved and/or straight edges). The substrate layers of display 14 may include glass layers, polymer layers, silicon layers, composite films that include polymer and inorganic materials, metallic foils, etc.

Display 14 may have an array of pixels 22 for displaying images for a user such as pixel array 28. Pixels 22 (e.g., microLEDs) in array 28 may be arranged in rows and columns. The edges of array 28 may be straight or curved (i.e., each row of pixels 22 and/or each column of pixels 22 in array 28 may have the same length or may have a different length). There may be any suitable number of rows and columns in array 28 (e.g., ten or more, one hundred or more, or one thousand or more, etc.). Display 14 may include pixels 22 of different colors. As an example, display 14 may include red pixels, green pixels, and blue pixels.

Display driver circuitry 20 may be used to control the operation of pixels 22. Display driver circuitry 20 may be formed from integrated circuits, thin-film transistor circuits, and/or other suitable circuitry. Illustrative display driver circuitry 20 of FIG. 2 includes display driver circuitry 20A and additional display driver circuitry such as gate driver circuitry 20B. Gate driver circuitry 20B may be formed along one or more edges of display 14. For example, gate driver circuitry 20B may be arranged along the left and right sides of display 14 as shown in FIG. 2.

As shown in FIG. 2, display driver circuitry 20A (e.g., one or more display driver integrated circuits, thin-film transistor circuitry, etc.) may contain communications circuitry for communicating with system control circuitry over signal path 24. Path 24 may be formed from traces on a flexible printed circuit or other cable. The control circuitry may be located on one or more printed circuits in electronic device 10. During operation, control circuitry (e.g., control circuitry 16 of FIG. 1) may supply circuitry such as a display driver integrated circuit in circuitry 20 with image data for images to be displayed on display 14. Display driver circuitry 20A of FIG. 2 is located at the top of display 14. This is merely illustrative. Display driver circuitry 20A may be located at both the top and bottom of display 14 or in other portions of device 10.

To display the images on pixels 22, display driver circuitry 20A may supply corresponding image data to data lines D while issuing control signals to supporting display driver circuitry such as gate driver circuitry 20B over signal paths 30. With the illustrative arrangement of FIG. 2, data lines D run vertically through display 14 and are associated with respective columns of pixels 22.

Gate driver circuitry 20B (sometimes referred to as gate line driver circuitry or horizontal control signal circuitry) may be implemented using one or more integrated circuits and/or may be implemented using thin-film transistor circuitry on substrate 26. Horizontal control lines G (sometimes referred to as gate lines, scan lines, emission control lines, etc.) run horizontally through display 14. Each gate line G is associated with a respective row of pixels 22. If desired, there may be multiple horizontal control lines such as gate lines G associated with each row of pixels. Individually controlled and/or global signal paths in display 14 may also be used to distribute other signals (e.g., power supply signals, etc.).

Gate driver circuitry 20B may assert control signals on the gate lines G in display 14. For example, gate driver circuitry 20B may receive clock signals and other control signals from circuitry 20A on paths 30 and may, in response to the received signals, assert a gate line signal on gate lines G in sequence, starting with the gate line signal G in the first row of pixels 22 in array 28. As each gate line is asserted, data from data lines D may be loaded into a corresponding row of pixels. In this way, control circuitry such as display driver circuitry 20A and 20B may provide pixels 22 with signals that direct pixels 22 to display a desired image on display 14. Each pixel 22 may have a light-emitting diode and circuitry (e.g., thin-film circuitry on substrate 26) that responds to the control and data signals from display driver circuitry 20.

Gate driver circuitry 20B may include blocks of gate driver circuitry such as gate driver row blocks. Each gate driver row block may include circuitry such output buffers and other output driver circuitry, register circuits (e.g., registers that can be chained together to form a shift register), and signal lines, power lines, and other interconnects. Each gate driver row block may supply one or more gate signals to one or more respective gate lines in a corresponding row of the pixels of the array of pixels in the active area of display 14.

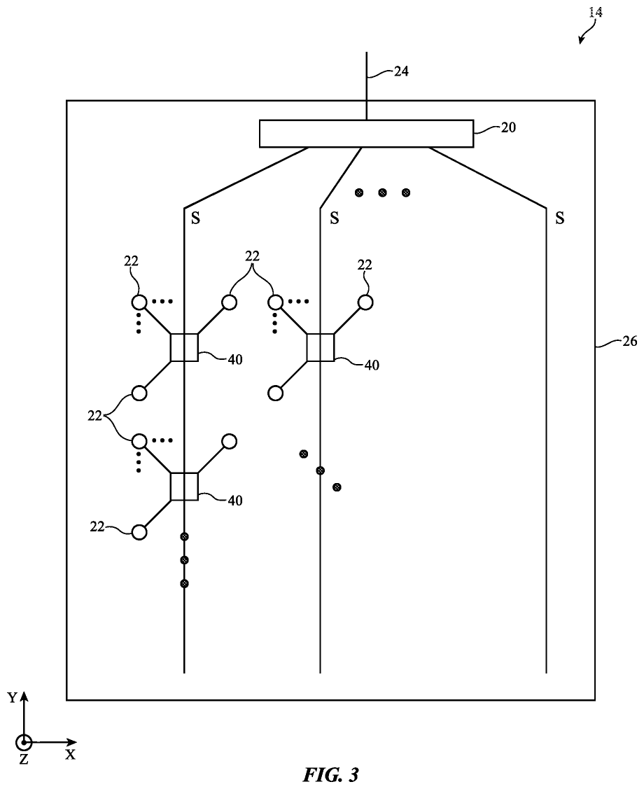

The active matrix addressing scheme of FIG. 2 is merely illustrative. If desired, display 14 may instead use pixel control circuits that address local passive matrices of pixels. An example of this type is shown in FIG. 3. As shown in FIG. 3, display 14 again may include layers such as substrate layer 26. Layers such as substrate 26 may be formed from layers of material such as glass layers, polymer layers, composite films that include polymer and inorganic materials, metallic foils, semiconductors such as silicon or other semiconductor materials, layers of material such as sapphire (e.g., crystalline transparent layers, ceramics, etc.), or other material. Substrate 26 may optionally be transparent (e.g., having a transparency greater than 80%, greater than 85%, greater than 90%, greater than 95%, greater than 98%, greater than 99%, etc.). Substrate 26 may be planar or may have other shapes (e.g., concave shapes, convex shapes, shapes with planar and curved surface regions, etc.). The outline of substrate 26 (e.g., when viewed from above along the Z-direction) may be circular, oval, rectangular, square, may have a combination of straight and curved edges, or may have other suitable shapes. As shown in the rectangular substrate example of FIG. 3, substrate 26 may have left and right vertical edges and upper and lower horizontal edges.

Display 14 may have an array of pixels 22 for displaying images for a user. Sets of one or more pixels 22 in FIG. 3 may be controlled using respective pixel control circuits 40 (sometimes referred to as driving circuits 40 or microdrivers 40). Pixel control circuits 40 may be formed using integrated circuits (e.g., silicon integrated circuits) and/or thin-film transistor circuitry on substrate 26. The thin-film transistor circuitry may include thin-film transistors formed from silicon (e.g., polysilicon thin-film transistors or amorphous silicon transistors) and/or may include thin-film transistors based on semiconducting oxides (e.g., indium gallium zinc oxide transistors or other semiconducting oxide thin-film transistors). Semiconducting oxide transistors such as indium gallium zinc oxide transistors may exhibit low leakage currents and may therefore be advantageous in configurations for display 14 where it is desirable to lower power consumption (e.g., by lowering the refresh rate for the pixels of the display). Configurations for display 14 in which pixel control circuits 40 are each formed from a silicon integrated circuit and a set of thin-film semiconducting oxide transistors may be used if desired.

Pixels 22 may be organized in an array (e.g., an array having rows and columns). Pixel control circuits 40 may be organized in an associated array (e.g., an array having rows and columns). As shown in FIG. 3, pixel control circuits 40 may be interspersed among the array of pixels 22. Pixels 22 and pixel control circuits 40 may be organized in arrays with rectangular outlines or may have outlines of other suitable shapes. There may be any suitable number of rows and columns in each array (e.g., ten or more, one hundred or more, or one thousand or more).

Each pixel 22 may be formed from a light-emitting component such as a light-emitting diode. If desired, each pixel may contain a pair of light-emitting diodes or other suitable number of light-emitting diodes for redundancy. In this type of configuration, the pair of light-emitting diodes in each pixel can be driven in parallel (as an example). In the event that one of the light-emitting diodes fails, the other light-emitting diode will still produce light. Alternatively or in addition, multiple pixel control circuits may be configured to control each pixel. In the event that one of the pixel control circuit fails, the other pixel control circuit will still control the pixel.

Display driver circuitry such as display driver circuitry 20 may be coupled to conductive paths such as metal traces on substrate 26 using solder or conductive adhesive. Display driver circuitry 20 may contain communications circuitry for communicating with system control circuitry over path 24. Path 24 may be formed from traces on a flexible printed circuit or other cable or may be formed using other signal path structures in device 10. The control circuitry may be located on a main logic board in an electronic device in which display 14 is being used. During operation, the control circuitry on the logic board (e.g., control circuitry 16 of FIG. 1) may supply circuitry such as display driver circuitry 20 with information on images to be displayed on display 14. To display the images on display pixels 22, display driver circuitry 20 may supply corresponding image data, control signals, and/or power supply signals to signal lines S. The signal lines provide corresponding image data, control signals, and power to the pixel control circuits 40. Based on the received power, image data, and control signals, the pixel control circuits 40 direct a respective subset of pixels 22 to generate light at desired intensity levels.

Signal lines S may carry analog and/or digital control signals (e.g., scan signals, emission transistor control signals, clock signals, digital control data, power supply signals, etc.). In some cases, a signal line may be coupled to a respective column of pixel control circuits 40. In some cases, a signal line may be coupled to a respective row of pixel control circuits 40. Each pixel control circuit 40 may be coupled to one or more signal lines. Circuitry 20 may be formed on the upper edge of display 14 (as in FIG. 3), on the lower edge of display 14, on the upper and left edges of display 14, on the upper, left, and right edges of display, or any other desired location(s) within display 14.

Display control circuitry such as circuitry 20 may be implemented using one or more integrated circuits (e.g., display driver integrated circuits such as timing controller integrated circuits and associated source driver circuits and/or gate driver circuits) or may be implemented using thin-film transistor circuitry implemented on substrate 26.

Pixels 22 may be organic light-emitting diode pixels or liquid crystal display pixels. Alternatively, pixels 22 in FIG. 3 may be formed from discrete inorganic light-emitting diodes (sometimes referred to as microLEDs). Pixels 22 may include light-emitting diodes of different colors (e.g., red, green, blue). Corresponding signal lines may be used to carry red, green, and blue data. Pixel arrangements of other colors may be used, if desired (e.g., four color arrangements, arrangements that include white pixels, three-pixel configurations with pixels other than red, green, and blue pixels, etc.). To produce different colors, the light-emitting diodes of pixels 22 may be constructed from different materials systems (e.g., AlGaAs for red diodes, GaN multiple quantum well diodes with different quantum well configurations for green and blue diodes, respectively), may be formed using different phosphorescent materials or different quantum dot materials to produce red, blue, and/or green luminescence, or may be formed using other techniques or combinations of these techniques. The light-emitting diodes of pixels 22 may radiate upwards (i.e., pixels 22 may use a top emission design) or may radiate downwards through substrate 26 (i.e., pixels 22 may use a bottom emission design). The light-emitting diodes may have thicknesses between 0.5 and 10 microns and may have lateral dimensions between 2 microns and 100 microns (as examples). Light-emitting diodes with other thicknesses (e.g., below 2 microns, above 2 microns, etc.) and that have other lateral dimensions (e.g., below 10 microns, below 20 microns, above 3 microns, above 15 microns, etc.) may also be used, if desired.

If desired, digital control signals can be provided to circuits 40 (over signal lines S), which may then produce corresponding analog light-emitting drive signals based on the digital control signals. During operation of display 14, each pixel control circuit 40 may supply output signals to a corresponding set of pixels 22 based on the control signals received by that pixel control circuit from display driver circuitry 20.

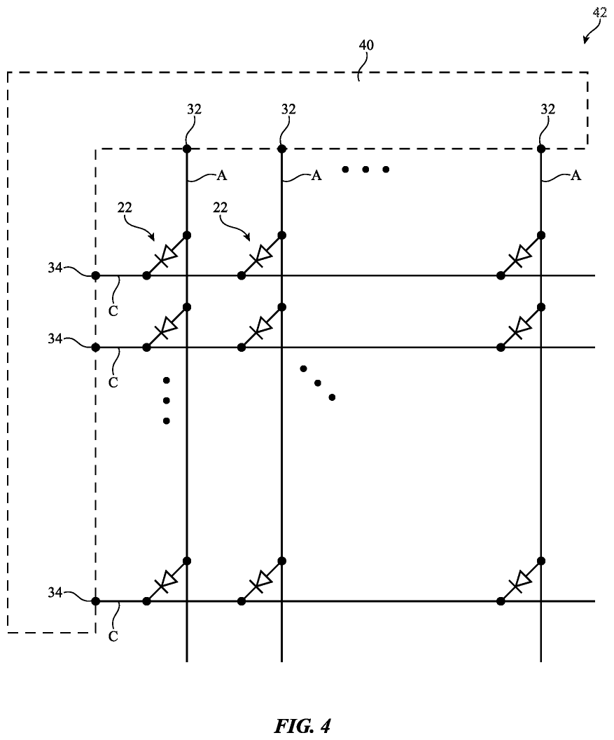

As one example, each pixel control circuit 40 may control a respective local passive matrix 42 of LED pixels 22. FIG. 4 is a schematic diagram of a local passive matrix 42 of LED pixels 22. As shown in FIG. 4, the anode of each LED 22 is coupled to a respective anode contact line A (sometimes referred to as anode contact A or anode line A). The LEDs 22 of each column in the passive matrix are connected to a common anode contact A. The cathode of each LED 22 is coupled to a respective cathode contact line C (sometimes referred to as cathode contact C or cathode line C). The LEDs 22 of each row in the passive matrix are connected to a common cathode contact C.

Pixel control circuit 40 may control the current and voltage provided to each anode line A. The pixel control circuit 40 may also control the voltage provided to each cathode contact line C. In this way, pixel control circuit 40 controls the current through each light-emitting diode 22, which controls the intensity of light emitted by each light-emitting diode. During operation of the passive matrix, pixel control circuit 40 may scan the pixels 22 row-by-row at high speeds to cause each LED 22 to emit light at a desired brightness level. In other words, each pixel in the first row is updated to a desired brightness level, then each pixel in the second row is updated to a desired brightness level, etc.

Pixel control circuit 40 may have first output terminals 32 that are coupled to the anode contact lines A and second output terminals 34 that are coupled to the cathode contact lines C. Pixel control circuit 40 may have one output terminal 32 per anode contact line and one output terminal 34 per cathode contact line, as one example. Using the passive matrix as in FIG. 4 therefore allows pixel control circuit 40 to control 64 light-emitting diodes (e.g., in an 8×8 grid) using only 16 outputs (8 anode output terminals and 8 cathode output terminals).

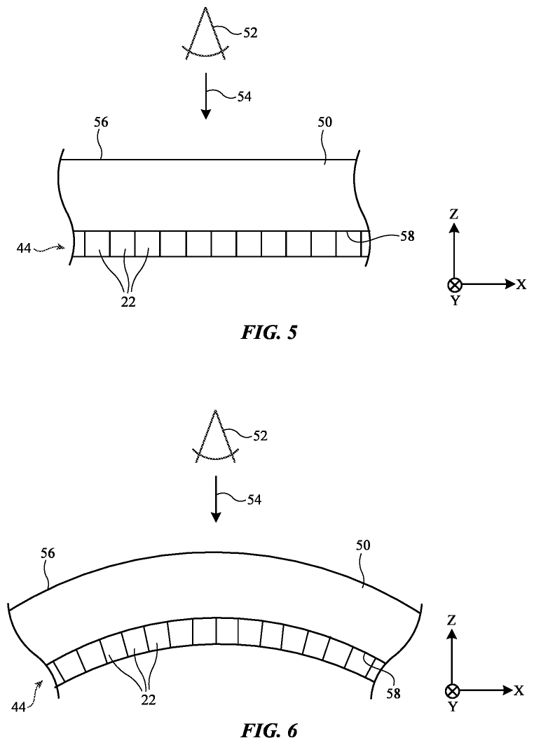

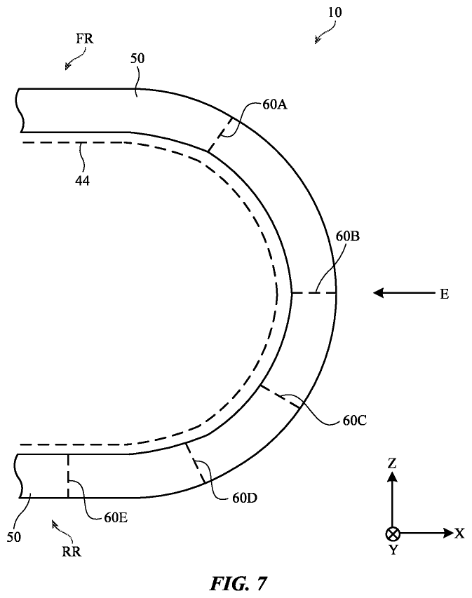

Transparent portions of device 10 may overlap pixels or other light-emitting components that emit light that is visible to a user. In the illustrative arrangements of FIGS. 5 and 6, an array of pixels 22 in layer 44 is configured to emit light that passes through display cover layer 50 for viewing by viewer 52 (e.g., in direction 54 and/or other directions from the exterior of device 10). The inner and outer surface of layers 50 (and other layers enclosing the interior of device 10) may be planar and/or curved. In the illustrative configuration of FIG. 5, outer surface 56 of layer 50 and inner surface 58 of layer 50 are planar. Inner surface 58 of FIG. 5 may be curved or partly planar and partly curved, if desired. In the illustrative configuration of FIG. 6, outer surface 56 of layer 50 is curved and inner surface 58 of layer 50 is curved. Inner surface 58 may, if desired, be planar or may have planar and curved surface profile portions.

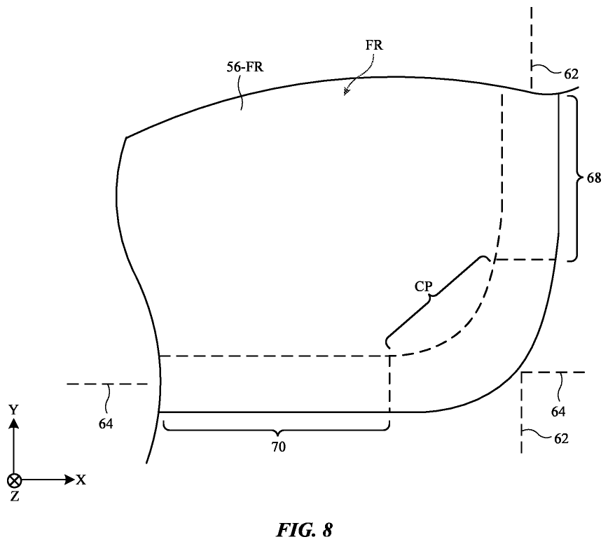

Device 10 may have upper and/or lower surfaces (e.g., external surfaces 56) that are planar and/or curved. The edges of device 10 may have sidewalls with planar and/or curved portions (e.g., surfaces with straight and/or curved profiles). As shown in FIG. 7, for example, the sidewalls of device 10 along one or more edges such as edge E of device 10 (e.g., a left edge, right edge, upper edge, lower edge, and/or the corners of device 10) may have a curved outer surface.

Edge E may be transparent (e.g., the entire sidewall of device 10 may be transparent and may be formed from extended portions of upper and lower display cover layer(s)) and/or one or more portions of the curved sidewall of edge E may be opaque (e.g., formed from glass or other material that is coated with opaque material, formed from opaque polymer, formed from metal, and/or formed from other opaque structures). Opaque structures (e.g., metal housing wall portions) may extend along one or more portions of edge E (e.g., metal or other opaque material may form the portion of edge E between locations 60A and 60B, between locations 60B and 60C, between locations 60C and 60D, between locations 60D and 60E, between locations 60A and 60C, between locations 60B and 60D, between locations 60C and 60E, or between other suitable locations on edge E). There may be a single strip of metal housing material that runs around all four peripheral edges E of device 10, there may be a pair of discrete strips of metal housing material that run around all four peripheral edges E in parallel, there may be no non-glass structures on edges E, and/or there may be other suitable structures on edges E.

Display layer 44 may be formed from a single panel (e.g., a single flexible organic light-emitting diode display panel having a polyimide substrate or other flexible substrate with bent edge portions), may be formed from multiple panels (e.g., multiple panels separated from one or more gaps), may be formed from panels with slots and other openings, and/or may be formed from other types of displays. Portions of display layer 44 (e.g., all of layer 44 and/or the pixels and/or other structures of layer 44) may be omitted wherever layer 44 is overlapped by a metal portion of edge E and/or other opaque structures in edge E. For example, edge E may be formed from glass everywhere except between locations 60B and 60D. The portion of edge (sidewall) E between locations 60B and 60D may be formed from metal (as an example). In this type of scenario, no display layer 44 (or at least no pixels 22) may be overlapped by the metal and pixels 22 and display layer 44 may be present under the glass portions of edge E and/or display cover layer 50 on front face FR and/or rear face RR.

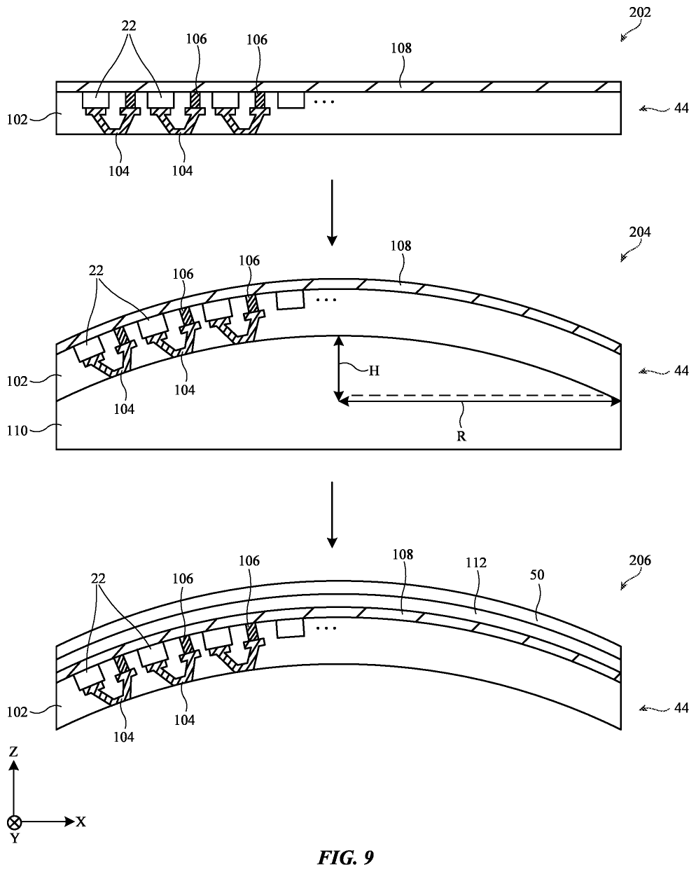

If desired, device 10 (and, correspondingly, display panel 44 and/or display cover layer 50) may have external surfaces with compound curvature. A perspective view of an illustrative corner portion of device 10 is shown in FIG. 8. In the example of FIG. 8, device 10 has edge portions (sidewalls) 68 and 70 with surfaces that curve about axes 62 and 64, respectively. These portions extend along the straight sides of device 10 and are characterized by curved surfaces that can be flattened into a plane without distortion (sometimes referred to as developable surfaces). At the corner of device 10, device 10 has curved surface portions CP with compound curvature (e.g., a surface that can only be flattened into a plane with distortion, sometimes referred to as a surface with Gaussian curvature). Each of the four corners of device 10 (and, correspondingly, display panel 44 and/or display cover layer 50) may have this arrangement, if desired.

Manufacturing displays with desired curvature may sometimes be difficult. Sharp curvature and/or compound curvature may create high strain in a display panel. If care is not taken, components in the display panel may not be sufficiently robust to handle the strain caused by the curvature. These components may crack, effectively breaking the functionality of the display panel. As a specific example, the display panel may include conductive traces formed from indium tin oxide (ITO). Indium tin oxide may only be able to handle small amounts of strain before breaking. Therefore, the curvature of a display panel with indium tin oxide components may be limited. The display panel may be cut to alleviate strain on the display components, but this results in visible seams in the display panel.

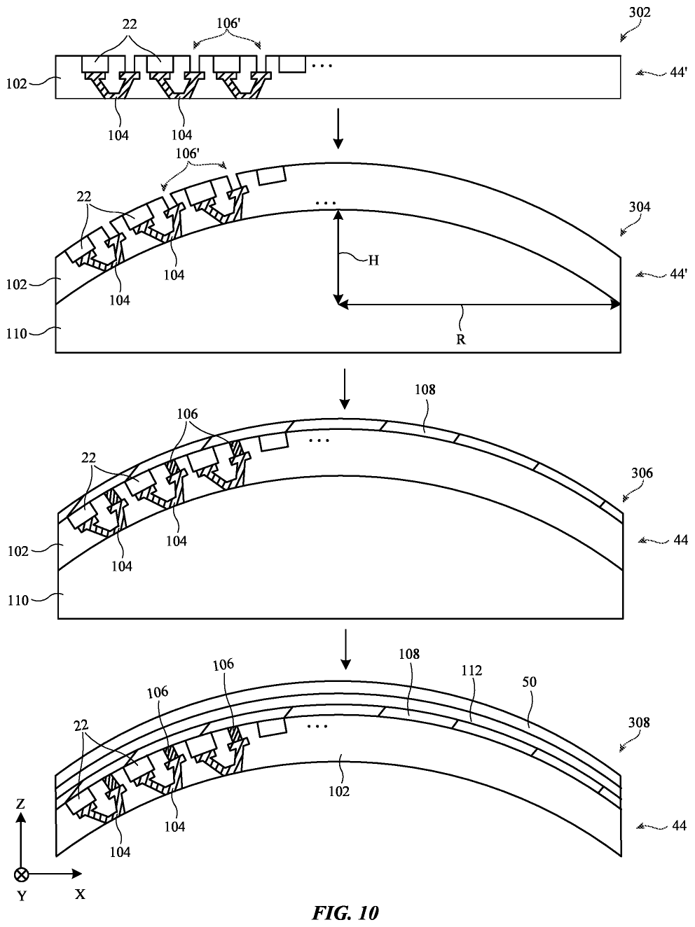

FIG. 9 is a cross-sectional side view of an illustrative process for forming a bent display panel. As shown in FIG. 9, at step 202, display panel 44 includes insulating layer(s) 102. Insulating layers 102 may include one or more non-conductive layers such as a polyimide substrate, transparent organic resin (e.g., planarization layers) that is formed between conductive layers in the display panel, etc. Insulating layers 102 selectively isolate conductive components in the display panel such as pixels 22, conductive routing layer(s) 104, vias 106, and traces 108.

In one possible arrangement, pixels 22 may be light-emitting diodes (e.g., microLEDs each formed from a crystalline semiconductor die). Red light-emitting diodes, green light-emitting diodes, and blue light-emitting diodes are all mounted on insulating layers 102 in display panel 44.

Conductive routing layers 104 may include signal lines, vias, contact pads, and/or other desired conductive components that convey signals to and from the light-emitting diodes 22. Conductive routing layers 104 may be formed from any desired conductive material (e.g., copper, silver, indium tin oxide, etc.)

Similar to the conductive routing layers, vias 106 and traces 108 may be formed from any desired conductive material (e.g., copper, silver, indium tin oxide, etc.). The conductive components in display panel 44 (e.g., conductive routing layers 104, vias 106, and traces 108) may be used to form data lines (e.g., data lines D in FIG. 2), gate lines (e.g., gate lines G in FIG. 2), signal lines (e.g., signal lines S in FIG. 3), anode lines (e.g., anode lines A in FIG. 4), and/or cathode lines (e.g., cathode lines C in FIG. 4) for display 14.

Next, at step 204, display panel 44 may be pressed into mold 110 (molded) to impart desired curvature onto display panel 44. Mold 110 may have a solid surface with target curvature for the display panel. When the display panel is pressed into mold 110 (optionally with a top mold that also has target curvature for the display panel), display panel 44 conforms to the mold. After display panel 44 is molded, display panel 44 has the target curvature.

FIG. 9 shows an example where display panel 44 is bent to have uniform convex curvature across the display panel. This example is merely illustrative. In another possible arrangement, the molded display panel may have a planar central portion and bent edge portions with target curvature imparted by mold 110.

Bending display panel 44 in step 204 results in stretching of components on an upper surface of the display panel such as traces 108. Traces 108 may be formed from a material such as indium tin oxide that is susceptible to breaking at low levels of strain (caused by the stretching). After bending, display panel 44 may have a bend characterized by H/R, where R (radius) is a lateral dimension of the display panel in the XY-plane from a start of the bend to the end of the bend and H (height) is the vertical separation (in the Z-direction, which is the direction light is emitted) between a surface of the display panel (e.g., the lower surface) at the start of the bend and at the end of the bend. In FIG. 9, traces 108 may be susceptible to breaking (due to strain from the bending) at H/R magnitudes of 0.02.

At step 206, display cover layer 50 is laminated to display panel 44 using optically clear adhesive 112. Display cover layer 50 may have similar curvature to display panel 44 (e.g., display panel 44 and display cover layer 50 may have conformal curvature).

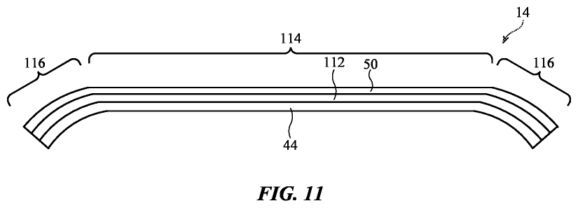

As previously mentioned, bending display panel 44 as in step 204 of FIG. 9 causes strain in display panel components. The maximum curvature that can be achieved using the method of FIG. 9 is therefore limited based on the amount of strain components such as traces 108 can handle. To obviate this issue, a different method may be used to form a bent display panel. In particular, the display panel may be partially formed in a planar state (including some but not all of the final display components). The partial display panel is then bent/molded to have desired curvature. After the partial display panel is bent, additional display components that are susceptible to damage during the bending process may be added to complete the display panel. FIG. 10 is a cross-sectional side view of an illustrative process of this type for forming a bent display panel.

As shown in FIG. 10, at step 302, a planar, partial display panel 44′ is formed. The partial display panel 44′ includes insulating layer(s) 102. Insulating layers 102 may include one or more non-conductive layers such as a polyimide substrate, transparent organic resin (e.g., planarization layers) that is formed between conductive layers in the display panel, etc. Insulating layers 102 selectively isolate conductive components in the partial display panel such as pixels 22 and conductive routing layer(s) 104.

In one possible arrangement, pixels 22 may be light-emitting diodes (e.g., microLEDs each formed from a crystalline semiconductor die). Red light-emitting diodes, green light-emitting diodes, and blue light-emitting diodes are all mounted on insulating layers 102 in display panel 44.

Conductive routing layers 104 may include signal lines, vias, contact pads, and/or other desired conductive components that convey signals to and from the light-emitting diodes 22. Conductive routing layers 104 may be formed from any desired conductive material (e.g., copper, silver, indium tin oxide, etc.)

At step 302, unfilled trenches 106′ may be included in insulating layers 102. However, vias 106 and traces 108 (e.g., from FIG. 9) are not included in the partial display panel 44′. These components may be omitted to allow for more aggressive curvature during the bending of the display panel without breaking the components.

Next, at step 304, partial display panel 44′ may be pressed into mold 110 (molded) to impart desired curvature onto partial display panel 44′. Mold 110 may have a solid surface with target curvature for the display panel. When the partial display panel is pressed into mold 110 (optionally with a top mold that also has target curvature for the partial display panel), partial display panel 44′ conforms to the mold. After partial display panel 44′ is molded, the partial display panel 44′ has the target curvature.

FIG. 10 shows an example where partial display panel 44′ is bent to have uniform convex curvature across the partial display panel. This example is merely illustrative. In another possible arrangement, the molded partial display panel may have a planar central portion and bent edge portions with target curvature imparted by mold 110.

Next, at step 306, additional conductive components such as vias 106 and traces 108 may be added to the bent partial display panel to form a completed display panel 44. Conductive routing layers 104, vias 106, and traces 108 may be used to form data lines (e.g., data lines D in FIG. 2), gate lines (e.g., gate lines G in FIG. 2), signal lines (e.g., signal lines S in FIG. 3), anode lines (e.g., anode lines A in FIG. 4), and/or cathode lines (e.g., cathode lines C in FIG. 4) for display 14.

Vias 106 and traces 108 may be formed from any desired conductive material (e.g., copper, silver, indium tin oxide, etc.). Because vias 106 and traces 108 are deposited (at step 306) after the partial display panel is already bent (at step 304), there are fewer limitations to the materials for vias 106 and traces 108. As an example, vias 106 and traces 108 may be formed from indium tin oxide. Because the indium tin oxide is deposited on an already bent (and correspondingly stretched) display panel, the display panel can have a high degree of curvature without causing the indium tin oxide components to break.

As shown in FIG. 10, the bent partial display panel 44′ (and the completed display panel 44) may have curvature characterized by H/R, where R (radius) is a lateral dimension of the display panel in the XY-plane from a start of the bend to the end of the bend and H (height) is the vertical separation (in the Z-direction, which is the direction light is emitted by the display) between a surface of the display panel (e.g., the lower surface) at the start of the bend and at the end of the bend. In FIG. 10, depositing sensitive components after the bending is complete may allow for the magnitude of H/R to be greater than 0.02 (i.e., a limitation in FIG. 9 due to the robustness of the strained indium tin oxide). In general, H/R in FIG. 10 may be greater than 0.01, greater than 0.02, greater than 0.05, greater than 0.1, greater than 0.2, less than 0.3, less than 0.2, less than 0.1, between 0.02 and 0.2, between 0.04 and 0.1, etc. Additionally, using the method of FIG. 10, display panel 44 may be formed with compound curvature (e.g., as shown and discussed in FIG. 8) without resulting in damage to sensitive components.

It should be noted that the bent portion of the display panel in FIG. 10 (optionally with compound curvature) does not have any cuts to alleviate strain. In other words, the display panel is continuous without seams/cuts throughout the bent portions (including bent portions with compound curvature).

To deposit traces 108 and/or vias 106 at step 306, a very precise deposition may be required. For example, traces 108 may be deposited (e.g., printed) on an upper surface of the bent partial display panel with micron-level resolution. The traces may be printed with widths that are less than 2 microns, less than 1 micron, etc. The traces may be separated by gaps that are less than 5 microns, less than 3 microns, etc. The traces may be printed on curved surfaces (e.g., surfaces with convex curvature, compound curvature, etc.), stepped surfaces, etc.

At step 308, display cover layer 50 is laminated to display panel 44 using optically clear adhesive 112. Display cover layer 50 may have similar curvature to display panel 44 (e.g., display panel 44 and display cover layer 50 may have conformal curvature).

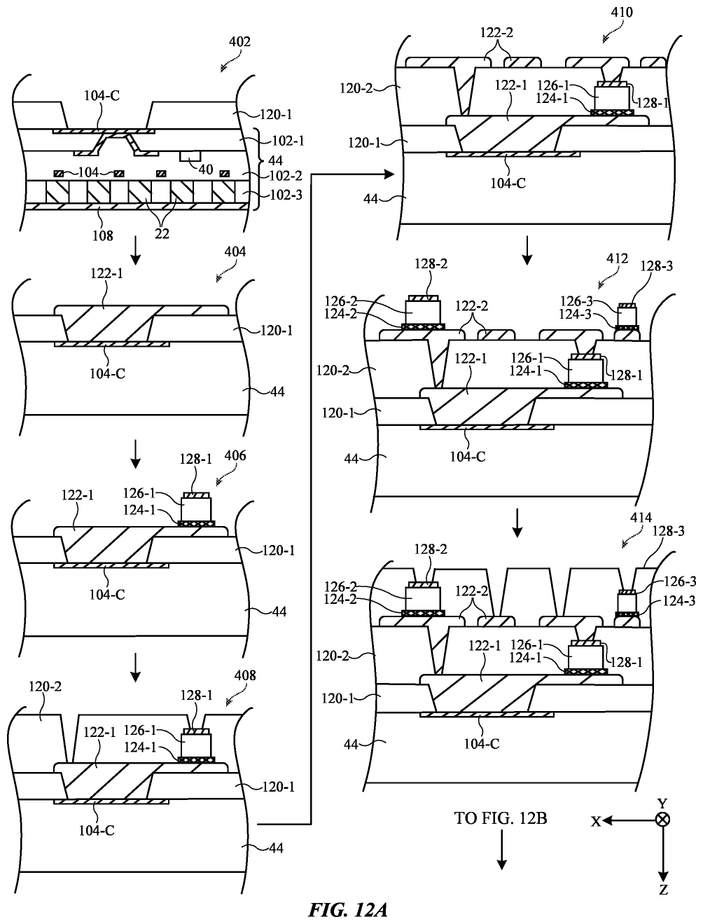

FIG. 11 is a cross-sectional side view of display 14 showing how the display may have a planar central portion (e.g., portion 114) and curved edge portions (e.g., portions 116). The curved edge portions may completely laterally surround the planar central portion (e.g., extend around the periphery of the planar central portion). The curved edge portions may have portions with curved surfaces that can be flattened into a plane without distortion (sometimes referred to as developable surfaces) and/or portions with compound curvature (e.g., as shown and discussed in connection with FIG. 8). Each of the four corners of display 14 in FIG. 11 may have compound curvature, if desired. Each of the four corners of display 14 may be separated by bent edge portions with developable surfaces, if desired.

In connection with FIG. 10, a precise deposition of conductive material is used to form conductive components on a bent partial display panel. This example is, however, merely illustrative. In another possible arrangement, precise deposition of conductive material may be used to form pressure-less interconnects between a display panel and other components.

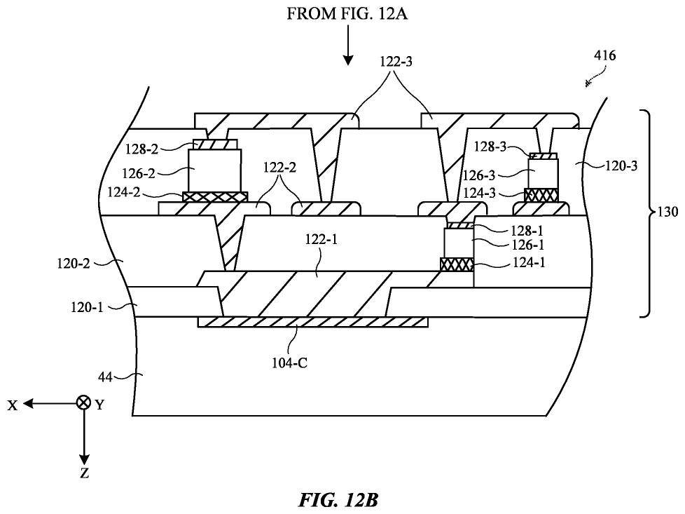

FIGS. 12A and 12B (sometimes collectively referred to as FIG. 12) are cross-sectional side views of an illustrative method for forming pressure-less interconnects that are attached to a display panel. Consider the display panel 44 shown at step 402 in FIG. 12. Display panel 44 includes insulating layers 102-1, 102-2, and 102-3. Insulating layer 102-1 may be, for example, a polyimide substrate. Insulating layer(s) 102-2 may include one or more insulating layers that separate various conductive layers within the display panel backplane. For example, at least four metal layers (conductive routing layers 104) may be interspersed between insulating layers 102-2. Insulating layers 102-2 may also conform to one or more pixel control circuits 40 that are distributed across the display panel (as shown in FIG. 3, for example). Light-emitting diodes 22 are formed on insulating layers 102-2. Conductive routing layers 104 may convey control signals from pixel control circuits 40 to light-emitting diodes 22. A planarization layer 102-3 may fill gaps between adjacent light-emitting diodes. Conductive traces 108 may be formed on an upper surface of planarization layer 102-3 (and may optionally be shorted to light-emitting diodes 22). It should be noted that in FIG. 12, the display panel is depicted as upside down. The display panel may be held in an upside-down position throughout the process of FIG. 12.

It should be noted that the internal structures of display panel 44 (shown at step 402) are omitted in steps 404-416 for clarity of the drawing. However, the same internal structures as shown at step 402 may be present (and unchanged) in each one of steps 404-416 in FIG. 12.

As shown in FIG. 12, at step 402 the display panel may have an exposed contact 104-C at its exterior surface (e.g., a lower surface when the display panel is in an upright orientation). This contact may be configured to be electrically connected to other components in display 14 and/or device 10 (e.g., a timing controller for display 14, a motherboard for device 10, etc.).

One technique for forming electrical connections to contact 104-C is to use an anisotropic conductive film (ACF). Anisotropic conductive film may serve as an interconnect structure between display panel 44 (e.g., contact 104-C) and an additional structure such as a flexible printed circuit (e.g., a contact on the flexible printed circuit). However, the anisotropic conductive film may require high pressure during attachment to ensure robust electrical and mechanical contact. In other words, the display panel and the flexible printed circuit need to be pushed together (with an intervening anisotropic conductive film). This lamination pressure may cause front-of-screen artifacts for display panel 44 (e.g., the display will have visible artifacts when observed by a viewer). In particular, the lamination pressure required for the anisotropic conductive film may damage the display panel in regions of the display with high levels of curvature and/or with compound curvature (due to high strain already present in these areas).

Therefore, instead of using anisotropic conductive film as an interconnect structure between display panel 44 and a flexible printed circuit, the flexible printed circuit may be formed directly on the display panel using precise deposition of conductive material. By forming the flexible printed circuit layer-by-layer directly on display panel 44, no substantive pressure needs to be applied to the display panel. Electrical connections may therefore be made to the display panel in regions of the display with high levels of curvature and/or with compound curvature without causing front-of-screen artifacts for display panel 44. FIG. 12 shows a method of this type, with a flexible printed circuit built layer-by-layer directly on display panel 44.

At step 402 in FIG. 12, a first dielectric layer 120-1 (sometimes referred to as insulating layer, isolation layer, etc.) may be patterned over display panel 44. The dielectric layer 120-1 may be patterned to have an opening that overlaps contact 104-C. Contact 104-C may be positioned on a bent portion of display panel 44 (optionally with compound curvature) or a planar portion of display panel 44.

Next, at step 404, a conductive layer 122-1 is deposited over dielectric layer 120-1. Conductive layer 122-1 may be deposited using precise deposition techniques (similar to as discussed above in connection with FIG. 10). Conductive layer 122-1 is in direct contact with contact 104-C, allowing the conductive layer to serve as an interconnect structure that is electrically connected to contact 104-C.

At step 406, an electrical component 126-1 may be attached to an upper surface of conductive layer 122-1 using a die attach film 124-1. The die attach film 124-1 is an adhesive film that has strong adhesion to conductive layer 122-1 and electrical component 126-1 without high pressure requirements. Electrical component 126-1 may have an exposed conductive contact 128-1 on its upper surface. The example of electrical component 126-1 being attached to an upper surface of conductive layer 122-1 is merely illustrative. Electrical component 126-1 may instead be attached to an upper surface of dielectric layer 120-1. However, die attach film 124-1 serves as an insulator that allows for the electrical component to be mounted on conductive material without being electrically connected to the conductive material.

Next, at step 408, a second dielectric layer 120-2 (sometimes referred to as insulating layer, isolation layer, etc.) may be patterned over dielectric layer 120-1, conductive layer 122-1 and electrical component 126-1. The dielectric layer 120-2 may be patterned to have a first opening (on the left in step 408 of FIG. 12) that overlaps an exposed portion of conductive layer 122-1 and a second opening (on the right in step 408 of FIG. 12) that overlaps an exposed portion of contact 128-1 for electrical component 126-1.

At step 410, a conductive layer 122-2 is deposited over dielectric layer 120-2. Conductive layer 122-2 may be deposited using precise deposition techniques (similar to as discussed above in connection with FIG. 10). In the example of FIG. 12, conductive layer 122-2 is deposited with multiple discrete portions. A first portion of conductive layer 122-2 is in electrical contact with conductive layer 122-1. A second portion of conductive layer 122-2 is in electrical contact with contact 128-1 of electrical component 126-1.

At step 412, an electrical component 126-2 may be attached to an upper surface of conductive layer 122-2 using a die attach film 124-2. The die attach film 124-2 is an adhesive film that has strong adhesion to conductive layer 122-2 and electrical component 126-2 without high pressure requirements. Electrical component 126-2 may have an exposed conductive contact 128-2 on its upper surface. Also at step 412, an electrical component 126-3 may be attached to an upper surface of conductive layer 122-2 using a die attach film 124-3. The die attach film 124-3 is an adhesive film that has strong adhesion to conductive layer 122-2 and electrical component 126-3 without high pressure requirements. Electrical component 126-3 may have an exposed conductive contact 128-3 on its upper surface.

Next, at step 414, a third dielectric layer 120-3 (sometimes referred to as insulating layer, isolation layer, etc.) may be patterned over dielectric layer 120-2, conductive layer 122-2 and electrical components 126-2 and 126-3. The dielectric layer 120-3 may be patterned to have first, second, third, and fourth openings. From left to right in step 414 of FIG. 12, the first opening that overlaps an exposed portion of contact 128-2 for electrical component 126-2, the second opening overlaps a portion of conductive layer 122-2, the third opening overlaps a portion of conductive layer 122-2, and the fourth opening overlaps an exposed portion of contact 128-3 for electrical component 126-3.

At step 416, a conductive layer 122-3 is deposited over dielectric layer 120-3. Conductive layer 122-3 may be deposited using precise deposition techniques (similar to as discussed above in connection with FIG. 10). In the example of FIG. 12, conductive layer 122-3 is deposited with multiple discrete portions. A first portion of conductive layer 122-3 is in electrical contact with contact 128-2 of electrical component 126-2 (and conductive layer 122-2) and a second portion of conductive layer 122-3 is in electrical contact with contact 128-3 of electrical component 126-3 (and conductive layer 122-2).

Conductive layers 122-1, 122-2, and 122-3 may be formed from any desired conductive materials (e.g., copper, silver, indium tin oxide, etc.). Dielectric layers 120-1, 120-2, and 120-3 may be formed from any desired material (e.g., polyimide). Dielectric layers 120-1, 120-2, and 120-3 may have a low melting point (and corresponding low cure temperature) so that the dielectric layers may be formed directly on display panel 44 without damaging display panel 44 during the manufacturing process. Dielectric layers 120-1, 120-2, and 120-3 may have a melting point that is less than 100 degrees Celsius, less than 90 degrees Celsius, less than 80 degrees Celsius, greater than 60 degrees Celsius, etc. Dielectric layers 120-1, 120-2, and 120-3 may be cured at a temperature that is less than 100 degrees Celsius, less than 90 degrees Celsius, less than 80 degrees Celsius, greater than 60 degrees Celsius, etc.

After the method steps of FIG. 12, a flexible printed circuit 130 is formed directly adjacent to and in direct contact with a lower surface of display panel 44. The flexible printed circuit 130 may conform to some or all of the lower surface of display panel 44 (including portions of the lower surface in bent portions of the display panel, optionally including bent portions with compound curvature). One or more electrical connections (e.g., between contact 104-C and conductive layer 122-1) formed without substantial lamination pressure are present between display panel 44 and flexible printed circuit 130.

In the example of FIG. 12, three electrical components 126-1, 126-2, and 126-3 are embedded within flexible printed circuit 130. These electrical components may be any desired electrical components (e.g., a timing controller for display 14, other integrated circuit dies, etc.). The example of flexible printed circuit 130 including embedded components is merely illustrative. If desired, flexible printed circuit 130 may include dielectric layers and conductive layers without any embedded components (e.g., the embedded components and corresponding die attach films may be omitted from FIG. 12).

The technique in FIG. 12 of forming a flexible printed circuit layer-by-layer directly on the lower surface of a display panel may be used for a completely planar/flat display panel (without any bends) or may be used for a bent display panel with one or bent portions and optionally with compound curvature.

The techniques of FIGS. 10 and 12 may be used in a single display if desired. For example, after the technique of FIG. 10 is used to form a display panel with curvature, the technique of FIG. 12 may be used to form a flexible printed circuit directly on a lower surface of the curved display panel.

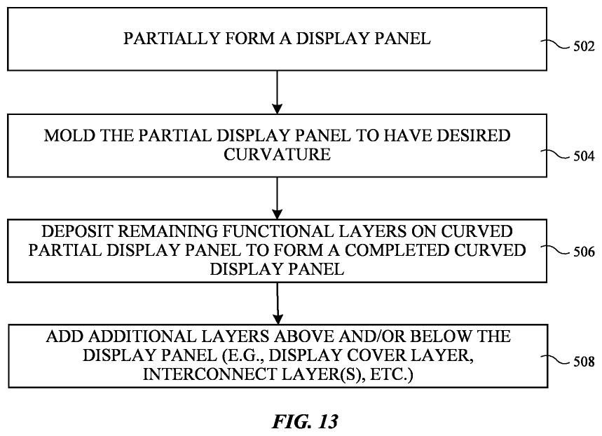

FIG. 13 is a flowchart of illustrative method steps that may be used to form a curved display panel (e.g., similar to as shown in FIG. 10). At step 502, a display panel may be partially formed (e.g., with LEDs and some conductive components formed among one or more insulating layers). Next, at step 504, the partial display panel may be molded to have desired curvature. The conductive components included in the partial display panel at step 502 may be sufficiently robust to handle strain caused by the bending of step 504.

After bending the partial display panel, remaining functional layers may be deposited on the curved partial display panel to form a completed curved display panel at step 506. The remaining functional layers deposited at step 506 may include conductive components such as conductive traces and/or conductive vias. The conductive components deposited at step 506 may be less robust to strain than the components formed in the display panel at step 502. However, because the conductive components at step 506 are deposited after the partial display panel is already bent, the conductive components at step 506 will not be exposed to high strain levels and will maintain their structural integrity.

Finally, at step 508, one or more additional layers may be added above and/or below the display panel. For example, a display cover layer may be laminated to the curved display panel with optically clear adhesive. The display cover layer and the display panel may have conformal curvature. As another option, one or more interconnect layers may be formed on a lower surface of the curved display panel (e.g., using the techniques of FIG. 12).

The example of depositing sensitive conductive layers on a curved structure may be applied to components other than a display. For example, a touch-sensitive display with curvature may include a touch sensor layer with curvature. To form the touch sensor layer, a touch sensor substrate may be molded to have desired curvature (similar to as in step 504). After the substrate is bent, sensitive conductive components such as conductive touch sensor traces may be deposited on the upper and/or lower surface of the bent substrate. The conductive touch sensor traces may be formed from a material such as indium tin oxide that cannot handle high strain. However, because the conductive touch sensor traces are formed on the substrate after the substrate is curved, the conductive touch sensor traces will not be exposed to high strain and will remain mechanically robust in the curved touch sensor layer. In general, this technique of molding/bending a partially formed structure then subsequently depositing sensitive components such as conductive traces may be applied to any desired electronic structures.

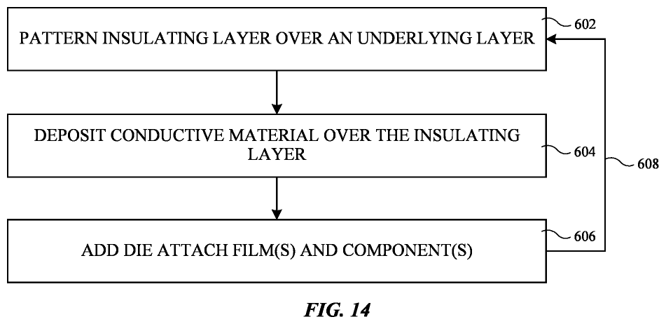

FIG. 14 is a flowchart of illustrative method steps that may be used to form a flexible printed circuit directly on a display panel (e.g., similar to as shown in FIG. 12). First, at step 602, an insulating layer may be patterned over an underlying layer. The insulating layer may be deposited as a blanket layer and then etched (e.g., using photolithography), as one example. The underlying layer may be a completely planar/flat display panel (without any bends), a bent display panel with one or bent portions, a bent display panel with compound curvature, etc. The insulating layer may be patterned to have at least one opening that exposes a conductive contact on the underlying layer (e.g., contact 104C in display panel 44 in FIG. 12).

Next, at step 604, conductive material may be deposited over the insulating layer formed at step 602. The conductive material may be deposited using precise deposition techniques. The conductive material may be deposited (e.g., printed) with micron-level resolution. The conductive material may be printed with widths that are less than 2 microns, less than 1 micron, etc. The conductive material may be separated by gaps that are less than 5 microns, less than 3 microns, etc. The conductive material may be printed on curved surfaces (e.g., surfaces with convex curvature, compound curvature, etc.), stepped surfaces, etc.

At step 606, any desired embedded components (e.g., components 126-1, 126-2, and 126-3 in FIG. 12) may be attached to an upper surface of the insulating layer from step 602 and/or the conductive material from step 604. Each component may be attached to an underlying layer with a respective adhesive layer (e.g., die attach film). Each component may have a conductive contact exposed on an upper surface of the component.

Steps 602-606 may be repeated as desired, as shown by loop 608. Each loop may add another insulating layer to the flexible printed circuit with a corresponding conductive layer and (optionally) embedded electrical components. In FIG. 12, the process of steps 602-606 is repeated three times (so that flexible printed circuit 130 ultimately has three insulating layers and conductive layers). This example is merely illustrative, and each flexible printed circuit formed using these techniques may have any desired number of layers.

The technique of FIG. 14 allows for pressure-free electrical connections to a lower surface of a display panel. This is advantageous for curved display panels (e.g., with compound curvature). Forming the electrical connections on a lower surface of the display panel (as opposed to an edge of an upper surface of the display panel) also mitigates the inactive border area required around the periphery of the display.

The foregoing is merely illustrative and various modifications can be made by those skilled in the art without departing from the scope and spirit of the described embodiments. The foregoing embodiments may be implemented individually or in any combination.

What is claimed is:

1. A method of forming a display panel with a first subset of conductive components and a second subset of conductive components, the method comprising:
forming a partial display panel, wherein the partial display panel includes the first subset of conductive components but not the second subset of conductive components;
bending the partial display panel to have at least one curved portion; and
after bending the partial display panel to have the at least one curved portion, adding the second subset of conductive components to the partial display panel to complete the display panel.

2. The method defined in claim 1, wherein the partial display panel includes a plurality of light-emitting diodes.

3. The method defined in claim 2, wherein each light-emitting diode of the plurality of light-emitting diodes is formed from a crystalline semiconductor die.

4. The method defined in claim 1, wherein bending the partial display panel to have the at least one curved portion comprises pressing the partial display panel over a mold with a curved surface.

5. The method defined in claim 1, further comprising:
after adding the second subset of conductive components to the partial display panel to complete the display panel, attaching a display cover layer to the display panel with a layer of optically clear adhesive.

6. The method defined in claim 1, wherein the at least one curved portion includes compound curvature.

7. The method defined in claim 1, wherein the partial display panel has four corners and wherein bending the partial display panel to have the at least one curved portion comprises bending the partial display panel to have compound curvature in each one of the four corners.

8. The method defined in claim 1, wherein the display panel is configured to emit light in a first direction, wherein the at least one curved portion includes a bend, wherein the bend is characterized by a first displacement in the first direction between a start of the bend and an end of the bend, wherein the bend is characterized by a second displacement in a second direction between the start of the bend and the end of the bend, wherein the second direction is orthogonal to the first direction, and wherein a ratio of the first displacement to the second displacement is greater than 0.02.

9. The method defined in claim 1, wherein the display panel is configured to emit light in a first direction, wherein the at least one curved portion includes a bend, wherein the bend is characterized by a first displacement in the first direction between a start of the bend and an end of the bend, wherein the bend is characterized by a second displacement in a second direction between the start of the bend and the end of the bend, wherein the second direction is orthogonal to the first direction, and wherein a ratio of the first displacement to the second displacement is greater than 0.1.

10. The method defined in claim 1, wherein the second subset of conductive components comprises conductive traces on an upper surface of the display panel.

11. The method defined in claim 10, wherein the conductive traces are formed from indium tin oxide.

12. A method of forming a flexible printed circuit adjacent to a display panel, wherein the display panel has a lower surface with a conductive contact, the method comprising:
patterning a first insulating layer directly on the lower surface of the display panel, wherein the first insulating layer has a first opening that overlaps the conductive contact of the display panel;
depositing a first conductive layer over the first insulating layer, wherein a portion of the first conductive layer directly contacts the conductive contact through the first opening;
patterning at least one additional insulating layer on the first insulating layer; and
depositing an additional conductive layer over each insulating layer of the at least one additional insulating layer.

13. The method defined in claim 12, wherein patterning the at least one additional insulating layer on the first insulating layer comprises patterning a second insulating layer on the first insulating layer and patterning a third insulating layer on the second insulating layer and wherein the second insulating layer includes a second opening that overlaps the first conductive layer.

14. The method defined in claim 13, wherein depositing the additional conductive layer over each insulating layer of the at least one additional insulating layer comprises depositing a second conductive layer over the second insulating layer and depositing a third conductive layer over the third insulating layer and wherein a portion of the second conductive layer directly contacts the first conductive layer through the second opening.

15. The method defined in claim 14, wherein the third insulating layer includes a third opening that overlaps the second conductive layer and wherein a portion of the third conductive layer directly contacts the second conductive layer through the third opening.

16. The method defined in claim 12, further comprising:
after depositing the first conductive layer over the first insulating layer, attaching an electrical component to a surface of the first conductive layer.

17. The method defined in claim 16, wherein attaching the electrical component to the surface of the first conductive layer comprises applying an adhesive layer between the surface of the first conductive layer and the electrical component.

18. The method defined in claim 17, wherein patterning the at least one additional insulating layer on the first insulating layer comprises patterning a second insulating layer on the first insulating layer, wherein the second insulating layer has an opening that overlaps a contact of the electrical component, wherein depositing the additional conductive layer over each insulating layer of the at least one additional insulating layer comprises depositing a second conductive layer over the second insulating layer, and wherein a portion of the second conductive layer directly contacts the contact of the electrical component.

19. An electronic device comprising:
a display panel that comprises at least one insulating layer, an array of light-emitting diodes on the at least one insulating layer, and conductive traces on an upper surface of the at least one insulating layer, wherein the conductive traces comprise indium tin oxide;
a display cover layer; and
a layer of optically clear adhesive that attaches the display cover layer to the display panel, wherein the display panel is configured to emit light in a first direction through the display cover layer, wherein the display panel has a bend, wherein the bend is characterized by a first displacement in the first direction between a start of the bend and an end of the bend, wherein the bend is characterized by a second displacement in a second direction between the start of the bend and the end of the bend, wherein the second direction is orthogonal to the first direction, and wherein a ratio of the first displacement to the second displacement is greater than 0.02.

20. The electronic device defined in claim 19, further comprising:
a flexible printed circuit that is formed in direct contact with and conforms to a lower surface of the display panel, wherein the flexible printed circuit includes an electrical connection to the lower surface of the display panel in a bent portion of the display panel that includes the bend.
